(19) United States
(12) Patent Application Publication
(10) Pub. No.: US 2007/0165379 A1
(43) Pub. Date: Jul. 19, 2007

(54) ELECTRONIC DEVICE

(75) Inventors: Arthur Chang, Taipei (TW); Fu-Ming Chen, Taipei (TW)

Correspondence Address: JIANQ CHYUN INTELLECTUAL PROPERTY OFFICE, 7 FLOOR-1, NO. 100, ROOSEVELT ROAD, SECTION 2, TAIPEI, 100, omitted

(73) Assignee: ASUSTeK COMPUTER INC., Taipei (TW)

(21) Appl. No.: 11/564,852

(22) Filed: Nov. 30, 2006

(30) Foreign Application Priority Data
Jan. 17, 2006 (CN) 200610001423.0

(51) Int. Cl. H05K 7/20

(52) U.S. Cl. 361/695

(57) ABSTRACT

An electronic device having a housing, a grating and at least a blade is provided. The housing has an opening and the grating covers the opening. The blade pivoted to the grating has many meshes. When an air current passes through the meshes, dust particles suspended in the air adhere to the meshes. After sufficient dust particles have accumulated over the meshes, the blade rotates.

### CROSS-REFERENCE TO RELATED APPLICATION

This application claims the priority benefit of China application serial no. 200610001423.0, filed Jan. 17, 2006. All disclosure of the China application is incorporated herein by reference.

### BACKGROUND OF THE INVENTION

1. Field of the Invention

The present invention relates to an electronic device and more particularly to an electronic device having blades with meshes.

2. Description of the Related Art

In recent years, the rapid development of technology has resulted in a variety of consumer electronic products being released in the market. With regard to a stationary electronic device such as a notebook computer, a mini desktop computer and so forth, the design of a heat dissipation system of the stationary electronic device has become increasingly important as the size of electronic device is getting smaller and the thermal power rate for internal components of the electronic device is getting higher. To optimize the heat-dissipating capacity, aside from using heat sinks and natural convection current to facilitate the cooling of the internal components of the electronic devices, the heat-dissipating system may include a fan to enhance the cooling effect.

FIG. 1A is a schematic cross-sectional view of a portion of a conventional electronic device. As shown in FIG. 1A, the housing 110 of the electronic device 100 has an air inlet 112. Furthermore, the electronic device 100 also has a grating 120 disposed over the air inlet 112. The air inlet 112 allows cooler air outside the housing 110 to flow into the interior of the electronic device 100 so that the heat generated by the internal electronic components (not shown) inside the housing 110 during high-speed operation is removed. Therefore, the internal electronic components are able to be cooled down and operate within an acceptable operating temperature range.

FIG. 2 shows a portion of the housing of the electronic device in FIG. 1A. To prevent small conductive objects such as clips, stapling pins or other objects from entering through the grating 120 into the interior of the electronic device 100 and leading to damages, a filter 130 is often installed on the grating 120 as shown in FIGS. 1A and 2. Moreover, the filter 130 can filter away a portion of the dust particles suspended in the air entering in the housing 110 so that a cleaner interior is maintained. FIG. 1B is a schematic cross-sectional view showing the grating and the filter in FIG. 1A dismantled from the electronic device. As shown in FIG. 1B, the filter 130 and the grating 120 can be detached from the electronic device 100 to facilitate cleaning.

In general, the air is full of floating dust particles or fabric fibers. These suspended dust particles or fabric fibers follow the air current into the interior of the housing 110 and then are intercepted by the filter 130. After a sufficient quantity of suspended dust particles or fabric fibers have accumulated on the filter 130, the area in the air inlet 112 for the passage of air through the air inlet 112 is significantly reduced. As a result, the heat-dissipating effect of the electronic device 100 is substantially compromised. Thus, if the grating 120 and the filter 130 thereon have a removable design, the user can dismantle the grating 120 and the filter 130 thereon and clear the filter 130 of dust particles or fabric fibers so that the original air flow area is reconstituted and the heat-dissipating capacity is restored.

However, the user may not have the habit of dismantling the filter 130 to clean it on regular basis, or is unaware of the dusty or dirt-filled condition of the filter 130. Hence, the suspended dust particles or fabric fibers adhered to the filter 130 will block the air inlet 112 and thus reduce the area of the air inlet, which the airflow can passed through, so as to adversely affect the heat-dissipating capacity of the electronic device 100. If the situation is allowed to continue, the electronic device 100 may eventually breakdown.

### SUMMARY OF THE INVENTION

Accordingly, at least one objective of the present invention is to provide an electronic device having a blade with meshes for filtering dust, which is capable of reminding a user when it is the appropriate time to clean up the blade.

To achieve these and other advantages and in accordance with the purpose of the invention, as embodied and broadly described herein, the invention provides an electronic device. The electronic device comprises a housing, a grating and at least a blade. The housing has an opening and the grating covers the opening. The blade is pivoted to the grating and has a plurality of meshes.

In one embodiment of the present invention, the grating connects with the housing through a detachable manner.

In one embodiment of the present invention, the grating latches onto the housing.

In one embodiment of the present invention, the dust particles in the air current that passes through the grating adhere to the meshes.

In one embodiment of the present invention, the blade rotates when the meshes is covered with dust particles.

In one embodiment of the present invention, the blade further includes a blade frame and a filter, and the filter is mounted on the blade frame.

In one embodiment of the present invention, the electronic device further includes a protruding axle and the blade is pivoted to the protruding axle.

In the present invention, the blade has meshes serving to block foreign objects and filter dust particles. Furthermore, the user is able to detect whether the meshes of the blade have accumulated excess dust particles through the rotation of the blade. If the meshes have accumulated excess dust particles, the user can remove the blade for a thorough cleanup so that the heat-dissipating capacity of the electronic device can be restored.

It is to be understood that both the foregoing general description and the following detailed description are exemplary, and are intended to provide further explanation of the invention as claimed.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention. In the drawings,

FIG. 1A is a schematic cross-sectional view of a portion of a conventional electronic device.

FIG. 1B is a schematic cross-sectional view showing the filter in FIG. 1A dismantled from the electronic device.

FIG. 2 shows a portion of the housing of the electronic device in FIG. 1A.

FIG. 3A is a schematic cross-sectional view of a portion of an electronic device according to one embodiment of the present invention.

FIG. 3B is a schematic cross-sectional view showing the grating in FIG. 3A dismantled from the electronic device.

FIG. 4 is a schematic cross-sectional view showing a portion of the housing of the electronic device shown in FIG. 3A.

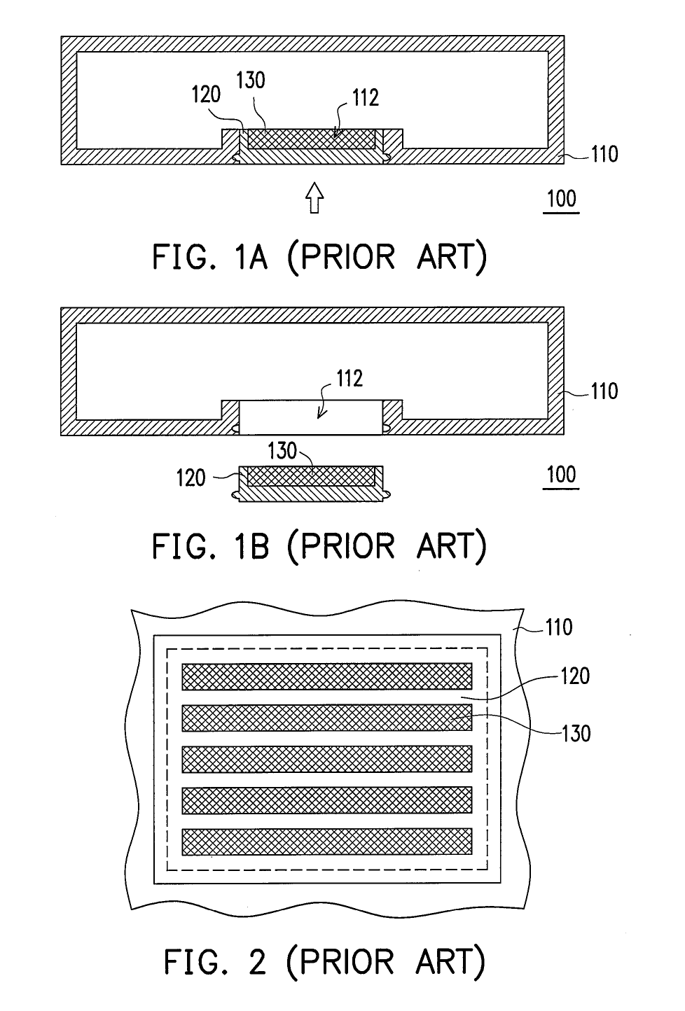

### DESCRIPTION OF THE PREFERRED EMBODIMENTS

Reference will now be made in detail to the present preferred embodiments of the invention, examples of which are illustrated in the accompanying drawings. Wherever possible, the same reference numbers are used in the drawings and the description to refer to the same or like parts.

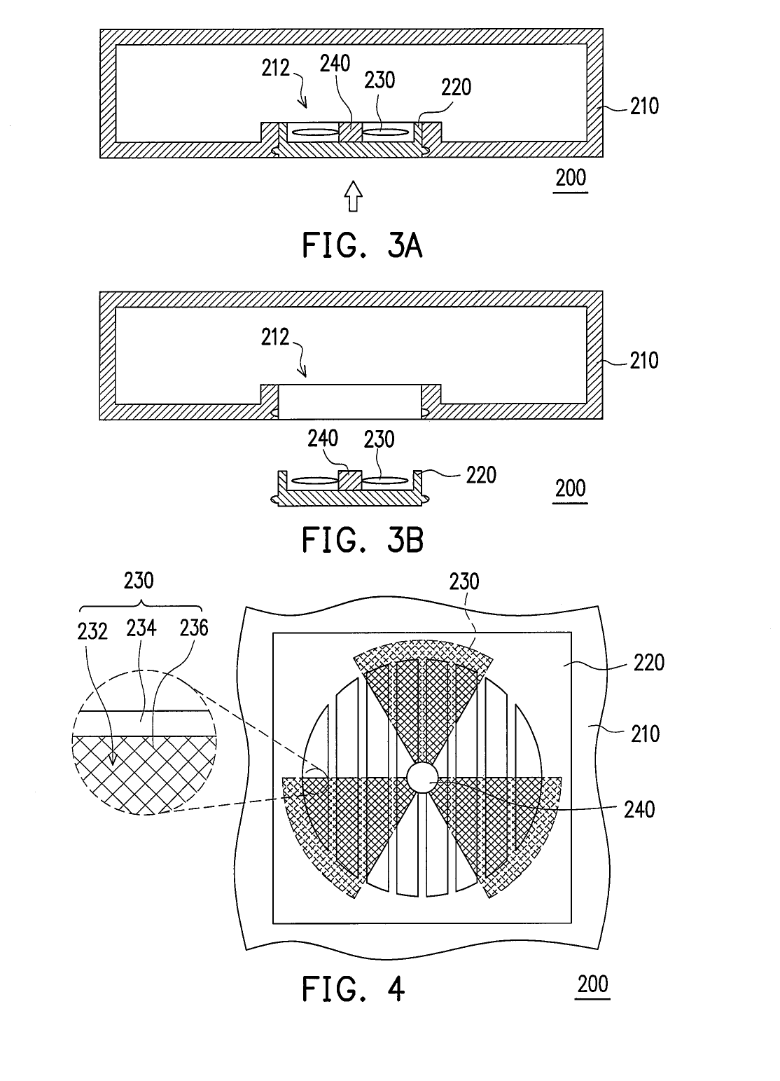

FIG. 3A is a schematic cross-sectional view of a portion of an electronic device according to one embodiment of the present invention. As shown in FIG. 3A, the electronic device 200, such as a portable computer or a notebook computer, includes a housing 210, a grating 220 and at least a blade 230. The housing 210 has an opening 212. The opening 212 can be located at the bottom or one side of the electronic device 200. The grating 220 connects with the housing 210 in a detachable manner and covers the opening 212. In the present embodiment, the opening 212 is an air inlet. Air outside the housing 210 of the electronic device 200 can enter through the opening 212 into the interior of the housing 210 by natural convection or forced circulation.

FIG. 3B is a schematic cross-sectional view showing the grating in FIG. 3A dismantled from the electronic device. FIG. 4 is a schematic cross-sectional view showing a portion of the housing of the electronic device shown in FIG. 3A. As shown in FIGS. 3B and 4, the grating 220 can be dismounted from the housing 210. The grating 220 may latch onto the housing 210 using a latching hook. Obviously, the grating 220 can engage to the housing 210 through a tight fitting structure or latch to the housing 210 by some other means. In addition, the blade 230 is pivoted to the grating 220 and the blade 230 has a plurality of meshes 232 thereon. In the present embodiment, the blade 230 further includes a blade frame 234 and a filter 236. The filter 236 is set up above the blade frame 234 such that the holes in the filter 236 are the meshes 232. The electronic device 200 further includes a protruding axle 240. The blade 230 is pivoted to the grating 220 through the protruding axle 240.

As shown in FIGS. 3A and 4, the internal electronic components (not shown) of the electronic device 200 will produce heat that warn up the surrounding air when the electronic device 200 is in operation. Thus, the cooler air inside the electronic device will induce a spontaneous localized natural convection with the hot air inside the electronic device 200. This natural convection air current will carry some of the hot air inside the electronic device 200 to the outside via other heat-dissipating holes (not shown) on the housing 210. In the meantime, cool air outside the housing 210 of the electronic device 200 enters into the interior of the electronic device 200 through the grating 220 and the meshes 232 of the blade 230. As a result, the air inside and outside the electronic device 200 links up to form a large natural convection system for removing the heat produced by the internal electronic components of the electronic device 200.

It should be noted that the air outside the electronic device 200 always contains varying amount of suspended dust particles such as ashes or fabric fibers. When cool air outside the electronic device 200 enters through the meshes 232, the ashes or fabric fibers will adhere to the meshes 232. In time, the ashes or fabric fibers on the meshes 232 will increase. As dust or fabric fibers gradually accumulates on the meshes 232, the air resistance of the cool air current outside of the housing 210 that entered through the meshes 232 will increase. Once there is sufficient dust or fabric fibers accumulated, the blade 230 will rotate. Hence, the rotating blade 230 can serve as a reminder reminding a user that it is time to remove the accumulated dust.

The rotation of the blade 230 can be detected through a sensor (not shown) and the user is reminded through a chime or a flashing light (not shown). Therefore, when the blade 230 rotates, the rotating blade 230 will trigger the sensor to drive an alarm sound or a flashing signal so that the user knows it is time to remove overloaded dust or fabric fibers. Moreover, the sensor can also connect with an operating system or an alarm circuit of the electronic device 200 so that one of the peripheral products of the electronic device 200 (for example, an image display device or a loudspeaker) is activated to remind the user.

In summary, the meshes of the blade used in the electronic device of the present invention have the capacity for blocking off foreign objects and filtering dust particles. Moreover, if the meshes of the blade are almost covered with dust or fabric fibers so that the resistant to air flow is increased above a threshold, the blade will rotate and trigger an alarm to remind the user that it is time to perform a clean up.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

What is claimed is:

1. An electronic device, comprising:
a housing having an opening;
a grating covering the opening; and
at least one blade pivoted to the grating, wherein the blade has a plurality of meshes thereon.

2. The electronic device of claim 1, wherein the grating and the housing are assembled using a detachable manner.

3. The electronic device of claim 1, wherein the grating is latched onto the housing.

4. The electronic device of claim 1, wherein the dust particles in the air current that passes through the grating adhere to the meshes.

5. The electronic device of claim 4, wherein the blade rotates when a sufficient quantity of dust particles has accumulated on the meshes.

6. The electronic device of claim 1, wherein the blade further includes a blade frame and a filter such that the filter is mounted on the blade frame.

7. The electronic device of claim 1, wherein the electronic device also has a protruding axle for pivoting the blade.
